(19) United States
(12) Patent Application Publication
(10) Pub. No.: US 2017/0040170 A1
(43) Pub. Date: Feb. 9, 2017

(54) Systems and Methods for Separately Applying Charged Plasma Constituents and Ultraviolet Light in a Mixed Mode Processing Operation

(71) Applicant: Lam Research Corporation, Fremont, CA (US)

(72) Inventors: Joydeep Guha, Danville, CA (US); Aaron Eppler, Fremont, CA (US)

(21) Appl. No.: 14/820,489

(22) Filed: Aug. 6, 2015

(51) Int. Cl. H01L 21/268; H01L 21/3065; H01L 21/67; H01J 37/32

(52) U.S. Cl. CPC H01L 21/2686; H01J 37/32082; H01J 37/3244; H01J 37/32715; H01L 21/3065; H01L 21/67069; H01L 21/67115; H01J 2237/334

(57) ABSTRACT

A processing volume is formed within an interior of a chamber between a top surface of a substrate support and a top dielectric window. An upper portion of the processing volume is a plasma generation volume. A lower portion of the processing volume is a reaction volume. A coil antennae is disposed above the dielectric window and connected to receive RF power. A process gas input is positioned to supply a process gas to the plasma generation volume. A series of magnets is disposed around a radial periphery of the chamber at a location below the top dielectric window. The series of magnets is configured to generate magnetic fields that extend across the processing volume. The series of magnets is positioned relative to the plasma generation volume such that at least a portion of the magnetic fields generated by the series of magnets is located below the plasma generation volume.

### BACKGROUND

1. Field of the Invention

The present invention relates to semiconductor device fabrication.

2. Description of the Related Art

Many modern semiconductor device fabrication processes utilize plasma-driven reactions to modify materials present on exposed surfaces of a substrate. For example, plasma etching processes can be used for patterning features within exposed materials on a substrate. The plasma used in the various plasma-driven fabrication processes is essentially a soup of neutral gas molecules, energetic electrons, ion, radicals, atoms, visible light, and ultraviolet (UV) light. A given plasma-driven fabrication process can be designed to rely more or less on different constituents of the plasma soup. For example, in some plasma-driven fabrication processes it may be more important to have ions interact with the materials on the substrate, and in other plasma-driven processes it may be more important to have radicals interact with the materials on the substrate. As the size of features within modern integrated circuit devices continues to shrink, it becomes more necessary to increase control over which constituents of the plasma are allowed to interact with the substrate at a given time in order to maintain feature critical dimension (CD) requirements and feature depth requirements, among requirements. And, due to the complex nature of the plasma, it can be difficult to exert control over which constituents of the plasma are allowed to interact with the substrate at a given time. It is within this context that the present invention arises.

### SUMMARY

In an example embodiment, a system for plasma processing is disclosed. The system includes a chamber having an exterior structure including one or more side walls, a bottom structure, and a top dielectric window. The system includes a substrate support structure disposed within an interior of the chamber. The substrate support structure has a top surface configured to support a substrate. A processing volume is formed within the interior of the chamber between the top surface of the substrate support and the top dielectric window. An upper portion of the processing volume is a plasma generation volume. A lower portion of the processing volume is a reaction volume. The system includes a coil antennae disposed above the dielectric window. The system includes a radiofrequency (RF) power source connected to supply RF power to the coil antennae. The system includes a process gas input positioned above the substrate processing volume. The system includes a process gas supply plumbed to supply process gas to the process gas input and into the plasma generation volume. The system includes a series of magnets disposed around a radial periphery of the chamber at a location below the top dielectric window. The series of magnets is configured to generate magnetic fields that extend across the processing volume. The series of magnets is positioned relative to the plasma generation volume such that at least a portion of the magnetic fields generated by the series of magnets is located below the plasma generation volume.

In an example embodiment, a method is disclosed for plasma processing of a substrate. The method includes placing a substrate in exposure to a processing volume within an interior of a chamber. The processing volume includes an upper portion that forms a plasma generation volume and a lower portion that forms a reaction volume. Plasma constituents generated within the plasma generation volume are required to travel through the reaction volume to reach the substrate. The method also includes generating a plasma within the plasma generation volume of the processing region. Generation of the plasma is localized to the plasma generation volume, with the reaction volume of the processing region being substantially free of plasma generation. The method also includes generating magnetic fields to extend across the processing volume. The magnetic fields are positioned vertically relative to the plasma generation volume such that at least a portion of the magnetic fields is located below the plasma generation volume and above the substrate. The magnetic fields are configured to trap ions and electrons from within the plasma to prevent the ions and electrons from moving downward to the substrate. The method also includes allowing UV light and radicals of the plasma to travel from the plasma generation volume through the reaction volume to the substrate.

In an example embodiment, a method is disclosed for plasma processing of a substrate. The method includes generating a helium plasma in exposure to a substrate at a location over the substrate. The method includes generating magnetic fields over the substrate to prevent ions and electrons of the helium plasma from reaching the substrate. The method includes allowing UV light from the helium plasma to interact with the substrate while ions and electrons of the helium plasma are prevented from reaching the substrate by the magnetic fields.

Other aspects and advantages of the invention will become more apparent from the following detailed description, taken in conjunction with the accompanying drawings, illustrating by way of example the present invention.

### BRIEF DESCRIPTION OF THE DRAWINGS

FIG. 1A shows a system for plasma processing that includes a plasma processing chamber, in accordance with some embodiments of the present invention.

FIG. 1B shows a horizontal cross-section view through the plasma processing chamber corresponding to reference View A-A as indicated in FIG. 1A, in accordance with some embodiments of the present invention.

FIG. 1C shows an alternate configuration of FIG. 1A in which the magnets are disposed within the side wall of the plasma processing chamber, in accordance with some embodiments of the present invention.

FIG. 1D shows an alternate configuration of FIG. 1A in which the magnets are disposed within the interior of the plasma processing chamber, in accordance with some embodiments of the present invention.

FIG. 2A shows the system of FIG. 1A in operation to generate a plasma, with the series of magnets (electromagnets) turned off, in accordance with some embodiments of the present invention.

FIG. 2B shows the system of FIG. 1A in operation to generate the plasma, with the series of magnets (electromagnets) turned on, in accordance with some embodiments of the present invention.

FIG. 3A shows the system of FIG. 1A, with two vertically separated series of magnets, in accordance with some embodiments of the present invention.

FIG. 3B shows the system of FIG. 3A, with the vertically separated series of magnets operated to generate a tilted magnetic field across the processing volume, in accordance with some embodiments of the present invention.

FIG. 3C shows the system of FIG. 1A, with five vertically separated series of magnets, in accordance with some embodiments of the present invention.

FIG. 4A shows a flowchart of a method for semiconductor device fabrication using the system of FIG. 1A, in accordance with some embodiments of the present invention.

FIG. 4B shows a flowchart of an alternate embodiment of the method of FIG. 4A, in which the operation for UV light photoreaction processing using the helium plasma is performed before the adsorption process instead of after the adsorption process, in accordance with some embodiments of the present invention.

FIG. 5 shows a method for plasma processing of a substrate, in accordance with some embodiments of the present invention.

FIG. 6 shows a method for plasma processing of a substrate, in accordance with some embodiments of the present invention.

### DETAILED DESCRIPTION

In the following description, numerous specific details are set forth in order to provide a thorough understanding of the present invention. It will be apparent, however, to one skilled in the art that the present invention may be practiced without some or all of these specific details. In other instances, well known process operations have not been described in detail in order not to unnecessarily obscure the present invention.

UV light is a spectral category of electromagnetic radiation having a wavelength (λ) within a range extending from 100 nanometers (nm) to 400 nm. The UV light spectrum can be divided into several spectral sub-categories including vacuum ultraviolet (VUV) (10 nm≦λ<200 nm), extreme ultraviolet (EUV) (10 nm≦λ<121 nm), hydrogen Lyman-alpha (H Lyman-α) (121 nm≦λ<122 nm), far ultraviolet (FUV) (122 nm≦λ<200 nm), ultraviolet C (UVC) (100 nm≦λ<280 nm), middle ultraviolet (MUV) (200 nm≦λ<300 nm), ultraviolet B (UVB) (280 nm≦λ<315 nm), near ultraviolet (NUV) (300 nm≦λ<400 nm), and ultraviolet A (UVA) (315 nm≦λ<400 nm). For ease of description, the term “UV light” in used herein to refer to electromagnetic radiation characterized by any one or more of the spectral sub-categories of the UV light spectrum.

In an example embodiment, the term “substrate” as used herein refers to a semiconductor wafer. However, it should be understood that in other embodiments, the term substrate as used herein can refer to substrates formed of sapphire, GaN, GaAs or SiC, or other substrate materials, and can include glass panels/substrates, metal foils, metal sheets, polymer materials, or the like. Also, in various embodiments, the substrate as referred to herein may vary in form, shape, and/or size. For example, in some embodiments, the substrate as referred to herein may correspond to a 200 mm (millimeters) semiconductor wafer, a 300 mm semiconductor wafer, or a 450 mm semiconductor wafer. Also, in some embodiments, the substrate as referred to herein may correspond to a non-circular substrate, such as a rectangular substrate for a flat panel display, or the like, among other shapes.

In some plasma-driven semiconductor device fabrication processes, UV light can be used to initiate reactions that serve to modify materials on a substrate. For example, in a plasma-driven etching operation, UV light can be used to initiate photo-reactions that serve to enhance the etch rate of one or more materials on the substrate. In another example, UV light can be used to dissociate the process gas to create desired chemical fragments. Therefore, it should be understood that plasma-generated UV light can be utilized to improve and/or affect various semiconductor fabrication processes. And, in some fabrication processes it may be desirable to control the processing effects of UV light separate from the processing effects of other plasma constituents, such as charged constituents including ions and electrons. For example, in some processing applications it may be desirable to separate exposure of the substrate to UV light and ion bombardment into separate discrete processing steps, thereby allowing one processing step to operate based primarily on UV light interaction without ion bombardment, with a different processing step operating primarily based on ion bombardment. Systems and methods are disclosed herein for controlling which plasma constituents (ions, electrons, radicals, UV light) are allowed to interact with the substrate at a given time in order to enhance control over plasma-driven fabrication processes, such as etching among others.

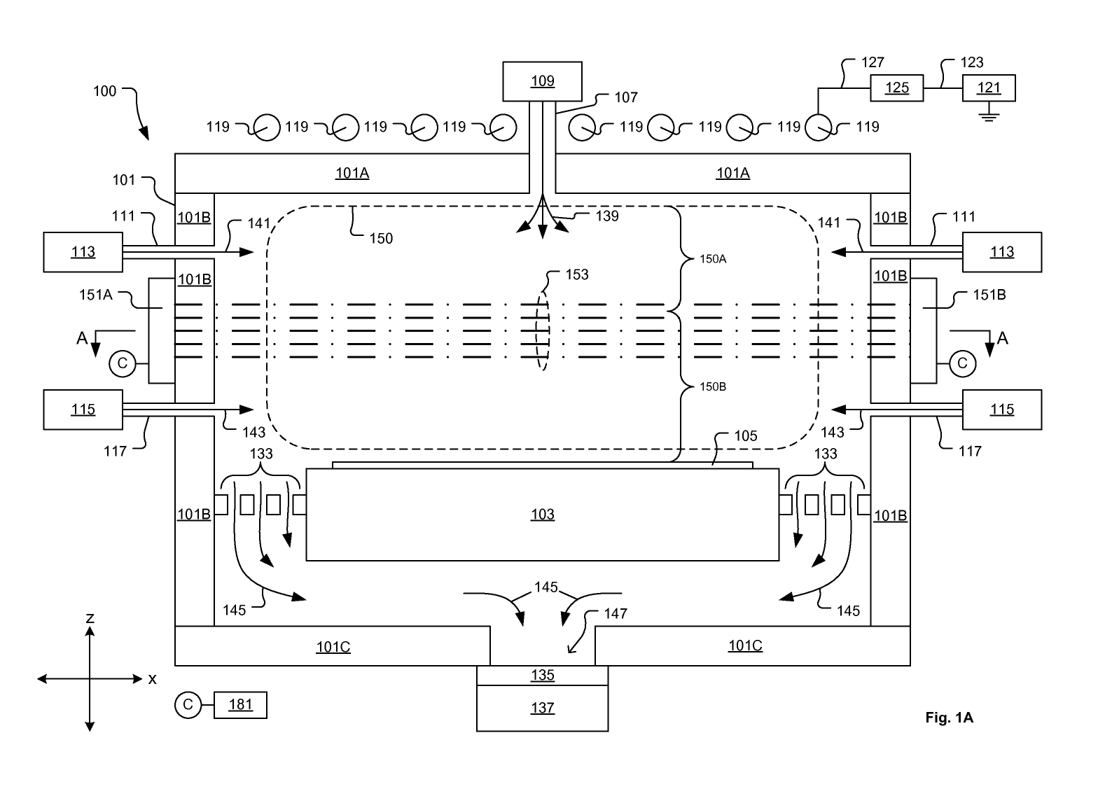

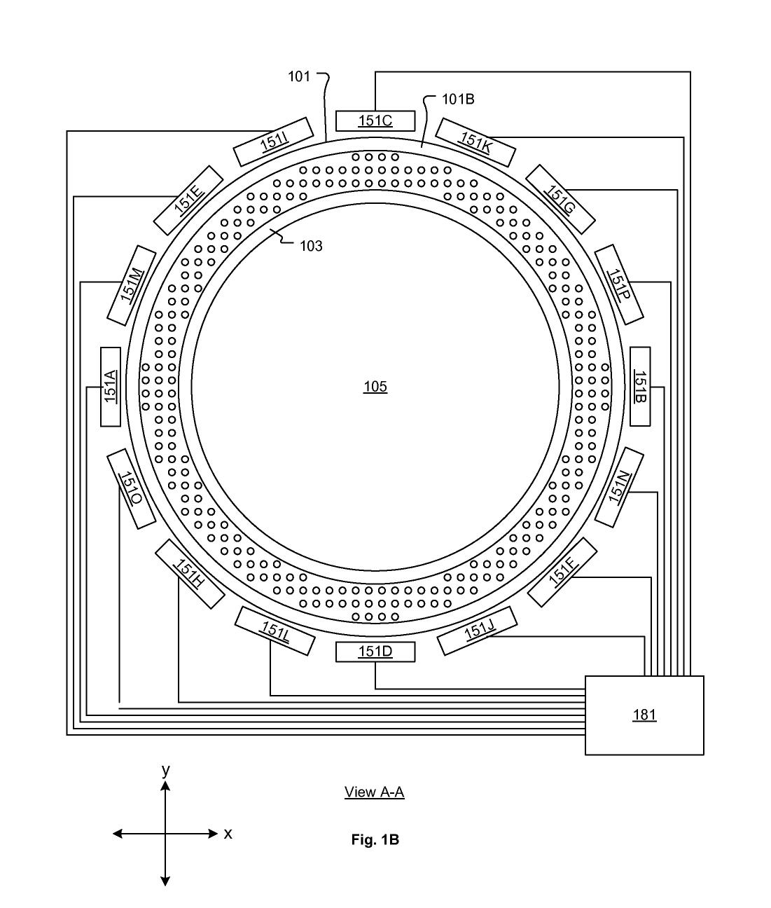

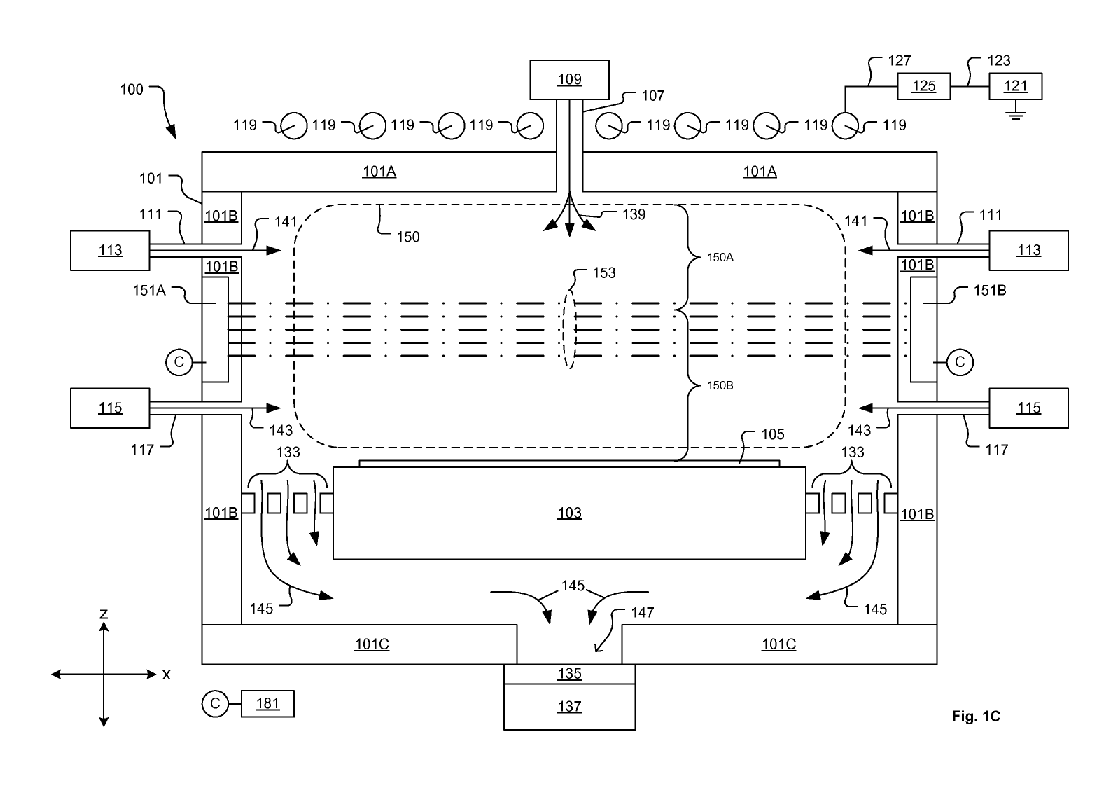

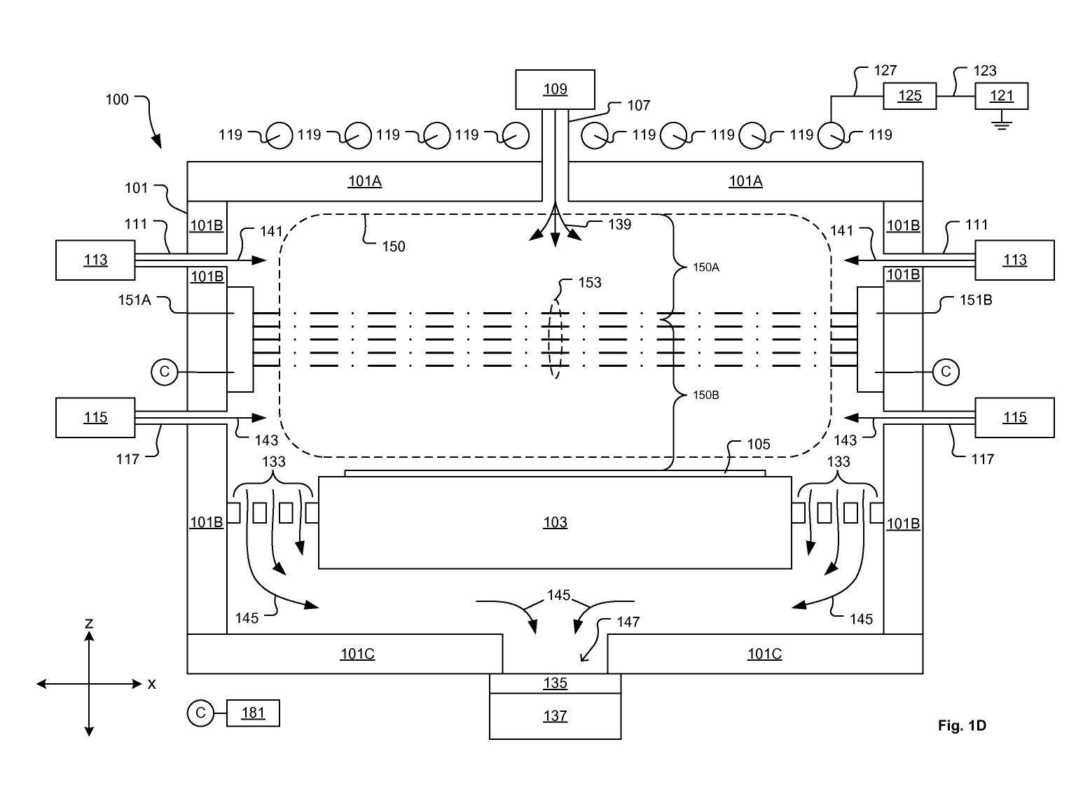

FIG. 1A shows a system 100 for plasma processing that includes a plasma processing chamber 101, in accordance with some embodiments of the present invention. The plasma processing chamber 101 is an example of an inductively coupled plasma (ICP) processing chamber. The plasma processing chamber 101 includes an exterior structure defined by one or more side walls 101B, a top dielectric window 101A, and a bottom structure 101C. In some embodiments, the side walls 101B and bottom structure 101C can be formed of an electrically conductive material and have an electrical connection to a reference ground potential. In some embodiments, the top dielectric window 101A is formed of a quartz or ceramic material. In some embodiments, the plasma processing chamber 101 can include a closable entryway through which a substrate 105 can be inserted into and removed from the plasma processing chamber 101. In other embodiments, an upper portion of the processing chamber 101 can be configured to separate from a lower portion of the process chamber 101 to enable insertion and removal of the substrate 105.

The plasma processing chamber 101 includes an electrostatic chuck 103 configured to support the substrate 105 and securely hold the substrate 105 during processing operations. A top surface of the electrostatic chuck 103 includes an area configured to support the substrate 105 during processing. In some embodiments, the electrostatic chuck 103 includes an upper ceramic layer upon which the substrate 105 is supported. In some embodiments, the upper ceramic layer of the electrostatic chuck 103 is formed by co-planar top surfaces of multiple raised structures referred to as mesa structures. With the substrate 105 supported on the top surfaces of the mesa structures, the regions between the sides of the mesa structures provide for flow of a fluid, such as helium gas, against the backside of the substrate 105 to provide for enhanced temperature control of the substrate 105. Also, in various embodiments, the electrostatic chuck 103 can be configured to include various cooling mechanisms, heating mechanisms, clamping mechanisms, bias electrodes, lifting pins, and/or sensors, among other components, where the sensors can provide for measurement of temperature, pressure, electrical voltage, and/or electrical current, among other parameters.

The plasma processing chamber 101 also includes a coil antennae 119 positioned above the top dielectric window 101A. A radiofrequency (RF) power source 121 is connected supply RF power to the coil antennae 119. Specifically, the RF power source 121 is connected to transmit RF signals through a connection 123 to a matching module 125. The impedance-matched RF signals are then transmitted from the matching module 125 through a connection 127 to the coil antennae 119. The matching module 125 is configured to match impedances so that the RF signals generated by the RF power source 121 can be transmitted effectively to a plasma load within the plasma processing chamber 101. Generally speaking, the matching module 125 is a network of capacitors and inductors that can be adjusted to tune impedance encountered by the RF signals in their transmission to the plasma processing chamber 101.

In various embodiments, the RF power source 121 can include one or more RF power sources operating at one or more frequencies. Multiple RF frequencies can be supplied to the coil antennae 119 at the same time. In some embodiments, frequencies of the RF power signals are set within a range extending from 1 kHz (kiloHertz) to 100 MHz (megaHertz). In some embodiments, frequencies of the RF power signals are set within a range extending from 400 kHz to 60 MHz. In some embodiments, the RF power source 121 is set to generate RF signals at frequencies of 2 MHz, 27 MHz, and 60 MHz. In some embodiments, the RF power source 121 is set to generate one or more high frequency RF signals within a frequency range extending from about 1 MHz to about 60 MHz, and generate one or more low frequency RF signals within a frequency range extending from about 100 kHz to about 1 MHz. The RF power source 121 can include frequency-based filtering, i.e., high-pass filtering and/or low-pass filtering, to ensure that specified RF signal frequencies are transmitted to the coil antennae 119. It should be understood that the above-mentioned RF frequency ranges are provided by way of example. In practice, the RF power source 121 can be configured to generate essentially any RF signal having essentially any frequency as needed to appropriately operate the plasma processing chamber 101.

The plasma processing chamber 101 also includes a process gas supply line 107 plumbed to supply a process gas from a process gas source 109 to a plasma generation volume 150A within the interior of the plasma processing chamber 101, as indicated by arrows 139. In some embodiments, the process gas supply line 107 is connected to a process gas delivery port located in a substantially centered position on the top dielectric window 101A. In some embodiments, the process gas delivery port includes a nozzle configured to spatially disperse the process gas into the plasma generation volume 150A in a substantially uniform manner. Also, in some embodiments, the plasma processing chamber 101 can optionally include a number of side tuning gas supply lines 111 plumbed to supply a side tuning gas from a side tuning gas source 113 to the plasma generation volume 150A at various locations azimuthally distributed around about radial centerline of the plasma processing chamber 101 (which extends in the z-axis direction), as indicated by arrows 141. In some embodiments, the side tuning gas can be the same as the process gas to provide for increased flow the process gas at the radial periphery of the plasma generation volume 150A. In some embodiments, the side tuning gas can be a different composition than the process gas, so as to provide an additional degree of freedom in establishing a prescribed gas mixture within the plasma generation volume 150A. It should be understood that in some embodiments the side tuning gas supply capability may not be present in the plasma processing chamber 101. However, in some embodiments, the side tuning gas supply capability may be implemented and/or utilized in lieu of the top process gas supply capability.

During operation, the process gas and/or side tuning gas is flowed into the plasma generation volume 150A, and the RF signals are supplied to the coil antennae 119. An electromagnetic field is generated by the RF signals transmitted through the coil antennae 119, thereby inducing electric fields within the plasma generation volume 150A which serve to excite components of the supplied process gas and/or side tuning gas to an extent at which the process gas and/or side tuning gas is transformed into a corresponding plasma. The reactive constituents of the plasma travel from the plasma generation volume 150A to a reaction volume 150B near the substrate 105, where the reactive constituents of the plasma can interact with the substrate 105 to provide desired processing effects. The plasma generation volume 150A and the reaction volume 150B collectively form a processing volume 150 overlying the electrostatic chuck 103 and substrate 105 supported thereon. In some embodiments, the plasma processing chamber 101 includes side vents 133 through which gases flow from the processing volume 150 to an exhaust port 147, as indicated by arrows 145. The exhaust port 147 is plumbed to an exhaust module 137 configured to apply a negative pressure for drawing gases and/or fluids from the interior of the plasma processing chamber 101. In some embodiments, an exhaust control valve 135 is provided at the exhaust port 147 to control the flow of gases through the exhaust port 147 to the exhaust module 137.

The plasma processing chamber 101 also includes a series of magnets 151A-151P disposed around a radial periphery of the plasma processing chamber 101 at a location below the top dielectric window 101A. The series of magnets 151A-151P is configured to generate a magnetic field that extends within the interior of the plasma processing chamber 101 and across the processing volume 150, as indicated in FIG. 1A by the horizontal lines 153 extending between the magnets 151A and 151B. In some embodiments, the series of magnets 151A-151P is configured to collectively generate the magnetic field in a manner such that the magnetic field extends horizontally, i.e., in the x-y axis plane, across an entirety of the interior of the plasma processing chamber 101. FIG. 1B shows a horizontal cross-section view through the plasma processing chamber 101 corresponding to reference View A-A as indicated in FIG. 1A, in accordance with some embodiments of the present invention. As shown in FIG. 1B, the series of magnets 151A-151P is disposed in a substantially uniform manner around the outer radial periphery of the plasma processing chamber 101. Therefore, the series of magnets 151A-151P are distributed in a substantially uniform azimuthal manner about the radial centerline of the plasma process chamber 101 (which extends in the z-axis direction). In some embodiments, the polarity of the magnets in the series of magnets 151A-151P can be alternated to obtain a desired magnetic field shape within the processing volume 150. It should be understood that the specific configuration (number, size, shape, location, etc.) of the series of magnets 151A-151P as depicted in FIGS. 1A and 1B is provided by way of example. In various embodiments, the number, size, shape, location, etc., of the magnets, e.g., 151A-151P, can vary as necessary to obtain a desired magnetic field shape across the interior of the plasma processing chamber 101.

In some embodiments, the magnets within the series of magnets 151A-151P are configured as electromagnets that can have their magnetic field generation turned on and off using electrical signals. In some embodiments, the magnets within the series of magnets 151A-151P are permanent magnets that continuously generate their magnetic field. In some embodiments, the series of magnets 151A-151P includes a combination of electromagnets and permanent magnets. When electromagnets are used for the series of magnets 151A-151P, each electromagnet can be connected to a magnetic field control system 181, as indicated by the connection C in FIG. 1A. The magnetic field control system 181 is configured to control the operation of each electromagnet in an independent manner, such that any one electromagnet can be turned on or off at a given time, and such that the magnetic field strength generated by any one electromagnet can be separately controlled at a given time. Also, the magnetic field control system 181 can be configured to process input signals from any type of sensor within the plasma processing chamber 101 and/or within any other component of the system 100, such as temperature sensors, pressure sensors, voltage sensors, current sensors, among others, in order to determine whether or not any particular electromagnet should have its magnetic field adjusted at a given time. Similarly, the magnetic field control system 181 can be configured to transmit signals to other components within the system 100 to advise of the current magnetic field generation status of any one or more of the electromagnets. The magnetic field control system 181 can also be configured to implement a real-time closed-loop feedback system to control the various magnetic fields generated by the various electromagnets in a manner that is responsive to conditions present within the plasma processing chamber 101.

The magnets 151A-151P are positioned in close enough proximity to the side wall 101B of the plasma processing chamber 101 to allow for penetration of their magnetic field within the interior of the plasma processing chamber 101. Also, the material of the side wall 101B of the plasma processing chamber 101 can be selected to allow for penetration of the magnetic fields into the interior of the plasma processing chamber 101. For example, in some embodiments, the portion of the side wall 101B of the plasma processing chamber 101 next to each magnet 151A-151P can be formed of aluminum, ceramic, or quartz, or essentially any other type of material that will not significantly attenuate the magnetic field generated by the magnet 151A-151P, while also providing chemical and structural capability for the processes performed within the plasma processing chamber 101. In some embodiments, such as that depicted in FIG. 1A, the magnets 151A-151P are disposed outside of the side wall 101B of the plasma processing chamber 101, so as to avoid exposure of the magnets 151A-151P to the plasma processing environment within the interior of the plasma processing chamber 101. FIG. 1C shows an alternate configuration of FIG. 1A in which the magnets 151A-151P are disposed within the side wall 101B of the plasma processing chamber 101, in accordance with some embodiments of the present invention. Positioning of the magnets 151A-151P within the side wall 101B of the plasma processing chamber 101 serves to reduce a thickness of the side wall 101B material that may attenuate the generated magnetic field while also avoiding exposure of the magnets 151A-151P to the plasma processing environment within the interior of the plasma processing chamber 101. FIG. 1D shows an alternate configuration of FIG. 1A in which the magnets 151A-151P are disposed within the interior of the plasma processing chamber 101, in accordance with some embodiments of the present invention. In the example embodiment of FIG. 1D, the magnets 151A-151P may be disposed within the interior of the plasma processing chamber 101, so long as the magnets 151A-151P are formed by or coated with material(s) that are chemically compatible with the plasma processing environment within the interior of the plasma processing chamber 101.

It is possible that the magnetic fields generated by the magnets 151A-151P can interfere with the electromagnetic fields generated by the coil antennae 119, thereby causing disruption of the plasma generation within the plasma generation volume 150A. Therefore, it may be necessary to maintain a vertical separation (in the z axis) between the magnets 151A-151P and the coil antennae 119. In some embodiments, the upper most edge of the series of magnets 151A-151P is vertically separated from the dielectric window 101A by a distance within a range extending from about 0.5 inch to about 6 inches. In some embodiments, the upper most edge of the series of magnets 151A-151P is vertically separated from the dielectric window 101A by a distance within a range extending from about 1.5 inches to about 3 inches. In some embodiments, the upper most edge of the series of magnets 151A-151P is vertically separated from the dielectric window 101A by a distance of about 2 inches. The term “about” as used herein means within +/−10% of a given value.

Also, the magnetic fields generated by the series of magnets 151A-151P should be vertically positioned relative to the plasma generation volume 150A such that essentially no plasma is generated at a vertical location below the magnetic fields. This vertical relationship between the magnetic fields and the plasma generation volume 150A ensures that the magnetic fields, or at least a portion thereof, are located between the charged constituents of the plasma and the substrate 105, so that the magnetic fields have an opportunity to trap the charged constituents of the plasma so as to prevent the charged constituents of the plasma from reaching the substrate 105. Also, the series of magnets 151A-151P should have a large enough vertical extent to provide for extension of their generated magnetic fields across the processing volume 150. In some embodiments, a magnetic field generation area of the series of magnets 151A-151P spans a vertical distance within a range extending from about 1 inch to about 2.5 inches. In some embodiments, a magnetic field generation area of the series of magnets 151A-151P spans a vertical distance of about 2 inches.

In some embodiments, a portion of a vertical expanse of the magnetic field generation area of the series of magnets 151A-151P is located radially outside the processing volume 150 so as to overlap both a portion of a vertical extent of the plasma generation volume 150A and a portion of the reaction volume 150B immediately below the plasma generation volume 150A. In some embodiments, a portion of the vertical expanse of the magnetic field generation area of the series of magnets 151A-151P is located radially outside the processing volume 150 so as to overlap essentially an entire vertical extent of the plasma generation volume 150A. In some embodiments, the vertical expanse of the magnetic field generation area of the series of magnets 151A-151P is located radially outside the processing volume 150 and vertically below the plasma generation volume 150A.

With reference back to FIG. 1A, the plasma processing chamber 101 can also optionally include a number of lower region gas supply lines 117 plumbed to supply a lower region gas from a lower region gas source 115 to the reaction volume 150B at various locations azimuthally distributed around about radial centerline of the plasma processing chamber 101 (which extends in the z-axis direction), as indicated by arrows 143. The lower region gas supply lines 117 are plumbed to dispense ports located at vertical positions below the series of magnets 151A-151P. In this configuration, the lower region process gas can be supplied to the reaction volume 150B without having to flow through the plasma generation volume 150A. Therefore, it is possible to avoid interaction of the lower region process gas with charged constituents of the plasma when the series of magnets are turned on to trap the charged constituents of the plasma within the plasma generation volume 150A. Also, while the example embodiment of FIG. 1A shows input of the lower region gas at a single vertical (z-axis) location, it should be understood that other embodiments can include multiple vertically separated lower region gas inputs and corresponding delivery systems.

It should be understood that the plasma processing chamber 101 is presented herein in a simplified manner for ease of description. In reality, the plasma processing chamber 101 is a complex system that includes many components not described herein. However, what should be appreciated for the present discussion is that the plasma processing chamber 101 is connected to receive controlled flows of one or more process gas composition(s) under carefully controlled conditions and includes the coil antennae 119 for transforming the one or more process gas composition(s) into the plasma within the plasma generation volume 150A to enable processing of the substrate 105 in a specified manner. Also, for the present discussion, it should be understood that at least one series of magnets 151A-151P is disposed around a periphery of the processing volume 150 to provide for generation of magnetic fields within the processing volume 150 in order to trap charged constituents of the plasma within the plasma generation volume 150A to affect various processing operations on the substrate 105. Examples of plasma processing operations that may performed by the plasma processing chamber 101 include etching operations, deposition operations, and ashing operations, among others. Also, it should be understood that the systems and methods disclosed herein with regard to disposing the at least one series of magnets 151A-151P around the processing volume 150 to provide for trapping of charged constituents of the plasma within the plasma generation volume 150A can be extended to other types of plasma processing chambers, such as capacitively coupled plasma (CCP) processing chambers and transformer coupled plasma (TCP) processing chambers, among others.

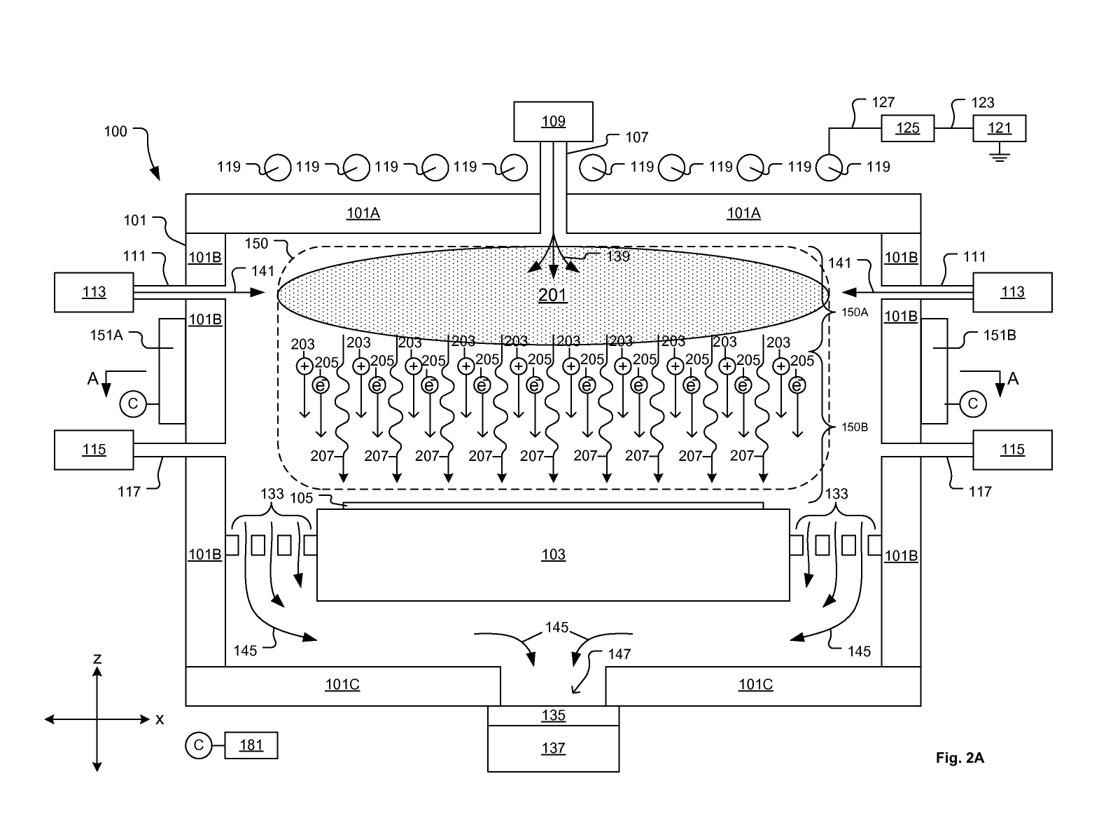

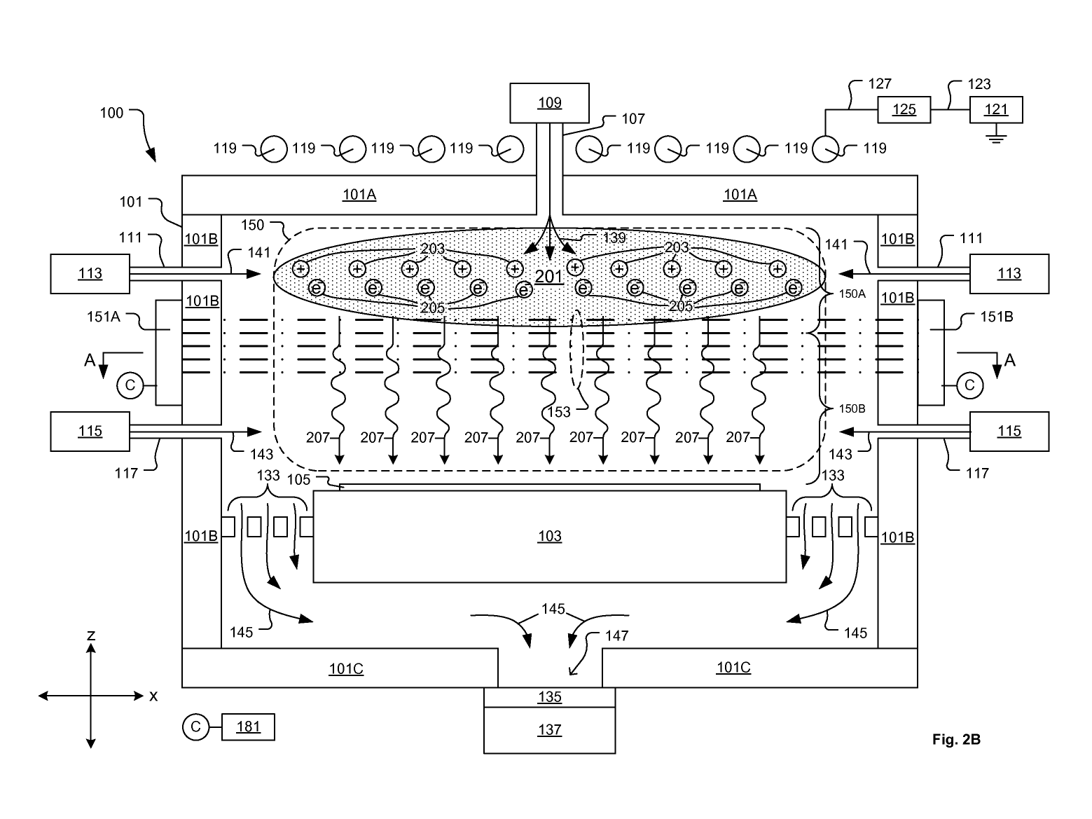

FIG. 2A shows the system 100 of FIG. 1A in operation to generate a plasma 201, with the series of magnets 151A-151P (electromagnets) turned off, in accordance with some embodiments of the present invention. As shown in FIG. 2A, the process gas is being supplied to the plasma generation volume 150A as indicated by arrows 139, and the side tuning gas is being optionally supplied to the plasma generation volume 150A as indicated by arrows 141, and RF power is being supplied to the coil antennae 119 to transform the process gas and/or side tuning gas into the plasma 201 within the plasma generation volume 150A. It should be noted that generation of the plasma 201 is localized to the plasma generation volume 150A and that the reaction volume 150B below the plasma generation volume 150A is substantially free of plasma generation.

The plasma 201 includes neutral gas molecules, electrons, ions, radicals, atoms, visible light, and UV light. The charged constituents of the plasma primarily include ions 203 and electrons 205. With the series of magnets 151A-151P turned off, any constituent of the plasma 201 is capable of moving into the reaction volume 150B toward the substrate 105. FIG. 2A depicts ions 203, electrons 205, UV light 207 traveling from the plasma 201 into the reaction volume 150B toward the substrate 105. Therefore, with the series of magnets 151A-151P turned off, the substrate 105 is exposed to not only UV light 207 emanating from the overlying plasma 201, but also to ions 203 and electrons 205.

When the ion 203 impacts the surface of the substrate 105, the ion 203 energy is imparted in a non-equilibrium process to induce a reaction on the substrate. Similarly, when UV light 207 is incident upon the surface of the substrate 105, the UV light 207 energy is imparted in a photo-initiation process to induce a reaction on the substrate. However, the impact of the ion 203 with the substrate 105 involves a significant amount of momentum transfer as compared to the UV light 207 interaction with the substrate 105. As a result, the effects on the substrate 105 due to ion 203 impact can be quite different that the effects due to UV light 207 exposure. Therefore, in comparison to ions 203, UV light 207 can be used to provide a softer activation of the substrate 105 surface, which can be useful for materials that are more prone to kinetically induced damage, such as low K dielectric materials. Thus, it can be beneficial to expose the substrate 105 to the UV light 107 emanating from the plasma 201 without exposing the substrate 105 to the ions 203 or electrons 205. To achieve this result, the series of magnets 151A-151P can be turned on to effectively trap the ions 203 and electrons 205 within the plasma 201, while continuing to allow exposure of the substrate 105 to the UV light 207.

FIG. 2B shows the system 100 of FIG. 1A in operation to generate the plasma 201, with the series of magnets 151A-151P (electromagnets) turned on, in accordance with some embodiments of the present invention. The magnetic fields generated by the series of magnets 151A-151P extend across the processing volume 150 to form a magnetic confinement plane for charged constituents of the plasma 201. The charged constituents of the plasma 201, including the ions 203 and electrons 205, are attracted to the magnetic field lines and move about the magnetic field lines, thereby effectively trapping them above the magnetic fields generated by the series of magnets 151A-151P. In this manner, the substrate 105 is exposed to the UV light 207 without being exposed to the ions 203 and electrons 205. Also, because the neutral constituents of the plasma 201, such as the radicals, are not affected by the magnetic fields, the neutral constituents will continue to move from the plasma 201 to the substrate 105. Therefore, with the series of magnets 151A-151P turned on, the substrate 105 is exposed to a soft plasma process that includes reactive exposure to primarily UV light 207 and radicals.

The series of magnets 151A-151P can be turned off to allow for exposure of the substrate 105 to charged constituents (ions 203 and electrons 205) of the plasma 201, and turned on to prevent exposure of the substrate 105 to charged constituents (ions 203 and electrons 205) of the plasma 201, while the UV light 107 bathes the substrate 105 regardless of the operational state of the series of magnets 151A-151P. Therefore, the series of magnets 151A-151P can be turned on or off in different process steps to obtain different process results on the substrate 105. Also, the magnetic field strength generated by the series of magnets 151A-151P at a given time can be controlled to allow for control of how strongly the charged constituents of the plasma 201 are trapped. With a lower strength magnetic field generated by the series of magnets 151A-151P, more charged constituents (ions 203 and electrons 205) will be allowed to reach the substrate 105. And, with a higher strength magnetic field generated by the series of magnets 151A-151P, less charged constituents (ions 203 and electrons 205) will be allowed to reach the substrate 105. Also, in some embodiments, the strength of the magnetic field generated by a given one of the magnets 151A-151P can be controlled to be higher or lower than others of the magnets 151A-151P, so as to enable generation of controlled magnetic field gradients across the processing volume 150. Therefore, in some embodiments, both the spatial configuration and the strength of the magnetic fields across the processing volume 150 (in the x-y plane), relative to the substrate 105, can be controlled to provide for control of charged constituent flux exposure at a given location on the substrate 105.

Additionally, because the plasma 201 composition at a given location is in part a function of the charged constituent density in the plasma 201 at the given location, and because the charged constituents of the plasma 201 are attracted to the magnetic fields generated by the series of magnets 151A-151P, it is possible to use the series of magnets 151A-151P to spatially control the plasma 201 composition. For example, operation of the series of magnets 151A-151P to generate higher magnetic fields at a particular location within the plasma generation volume 150A will attract more ions 203 in the plasma 201 to the particular location, which will in turn increase dissociation in the plasma 201 at the particular location causing generation of more radicals a the particular location. Therefore, by operating the series of magnets 151A-151P to control the spatial variation in the magnetic fields within the plasma generation volume 150A, it is possible to spatially control the composition of the plasma 201 with regard to both charged constituents and radicals. By spatially controlling the strength of the magnetic fields generated by the series of magnets 151A-151P across the processing volume 150, it is possible to spatially control the exposure of the substrate 105 to different plasma 201 constituents in a selective manner. For instance, by spatially controlling the strength of the magnetic fields generated by the series of magnets 151A-151P across the processing volume 150, it is possible to expose a particular location of the substrate 105 to more ions, or to less ions, or to more radicals, or to less radicals. Also, by spatially controlling the strength of the magnetic fields generated by the series of magnets 151A-151P across the processing volume 150, it is possible to process the substrate 105 in an intentionally non-uniform manner, which may be useful in correcting some non-uniformity previously introduced on the substrate 105.

The UV light 207 can be used for photo-initiation of reactions, as previously mentioned, and/or photo-dissociation reactions. In some embodiments, the series of magnets 151A-151P can be turned on to trap the ions 203 and electrons 205 within the plasma 201, so as to provide a flux of UV light 207 and radicals from the plasma 201 to the reaction volume 150B, with the lower region gas supplied through the lower region gas supply lines 117, as indicated by arrows 143 in FIG. 2B. In these embodiments, the UV light 207 can interact with the lower region gas within the reaction volume 150B to dissociate the lower region gas into fragments. With a properly composed lower region gas, the fragments of the lower region gas as dissociated by the UV light 207 can be applied to process the substrate 105 surface. Also, the fragments of the lower region gas resulting from dissociation reactions caused by the UV light 207 can have significantly different characteristics than dissociation fragments generated by high energy electrons within the plasma 201. Therefore, operation of the chamber 101 to preferentially dissociate the lower region gas using UV light 207 extends the operational envelope of the system 100. In some embodiments, the process gas supplied to the plasma generation region 150A can include helium gas, which when transformed into a helium plasma (as the plasma 201) will generate a significant amount of UV light 207 for the dissociation reactions in the reaction volume 150B, with the charged constituents of the helium plasma being confined above the magnetic fields generated by the series of magnets 151A-151P. Also, the UV light 207 generated by the helium plasma 201 can serve to activate the surface of the substrate 105.

Also, in some embodiments, when more of a pure UV light 207 exposure of the substrate 105 is desired, the lower region gas can be supplied in a manner to sweep away radicals emerging from the overlying plasma 201, with the series of magnets 151A-151P operating to confine the charged constituents of the plasma 201 to the plasma generation volume 150A. Also, in some embodiments, when more of a pure radical exposure of the substrate 105 is desired, a process gas such as argon can be used to generate the plasma 201 with a relatively low yield of UV light 207, with the series of magnets 151A-151P operating to confine the charged constituents of the plasma 201 to the plasma generation volume 150A, such that radicals flow from the overlying plasma 201 to the substrate 105 with a relatively low exposure of the substrate 105 to UV light 107. And, in some variations of these embodiments, the lower region gas can include one or more gases that have a high UV light absorption characteristic, such that the already lower amount of UV light 207 emanating from the plasma 201 due to the argon process gas can be further reduced through absorption by the lower region gas before reaching the substrate 105.

In some embodiments, the series of magnets 151A-151P can be formed by permanent magnets instead of electromagnets. In these embodiments, the plasma processing chamber 101 having the series of permanent magnets 151A-151P will have a perpetual magnet confinement plane present to trap charged constituents of the plasma 201 within the plasma processing region 150A. Therefore, the plasma processing chamber 101 having the series of permanent magnets 151A-151P will be specialized for soft plasma processing of the substrate 105 through exposure to a combination of UV light 207 and radicals, with limited to zero exposure of the substrate 105 to ions 203 and electrons 205, depending on the magnetic field strength of the permanent magnets 151A-151P. Also, with the use of permanent magnets 151A-151P, the polarity of the different magnets 151A-151P can be arranged to shape the resulting magnetic field within the processing volume 150 as needed.

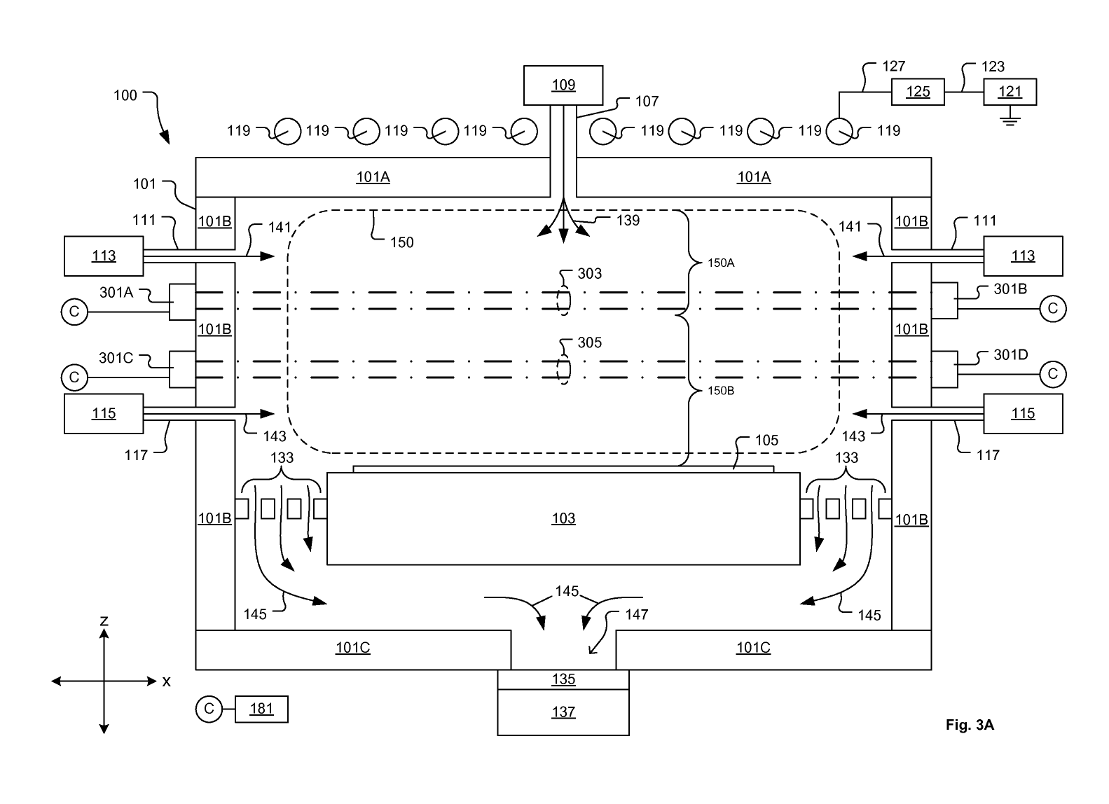

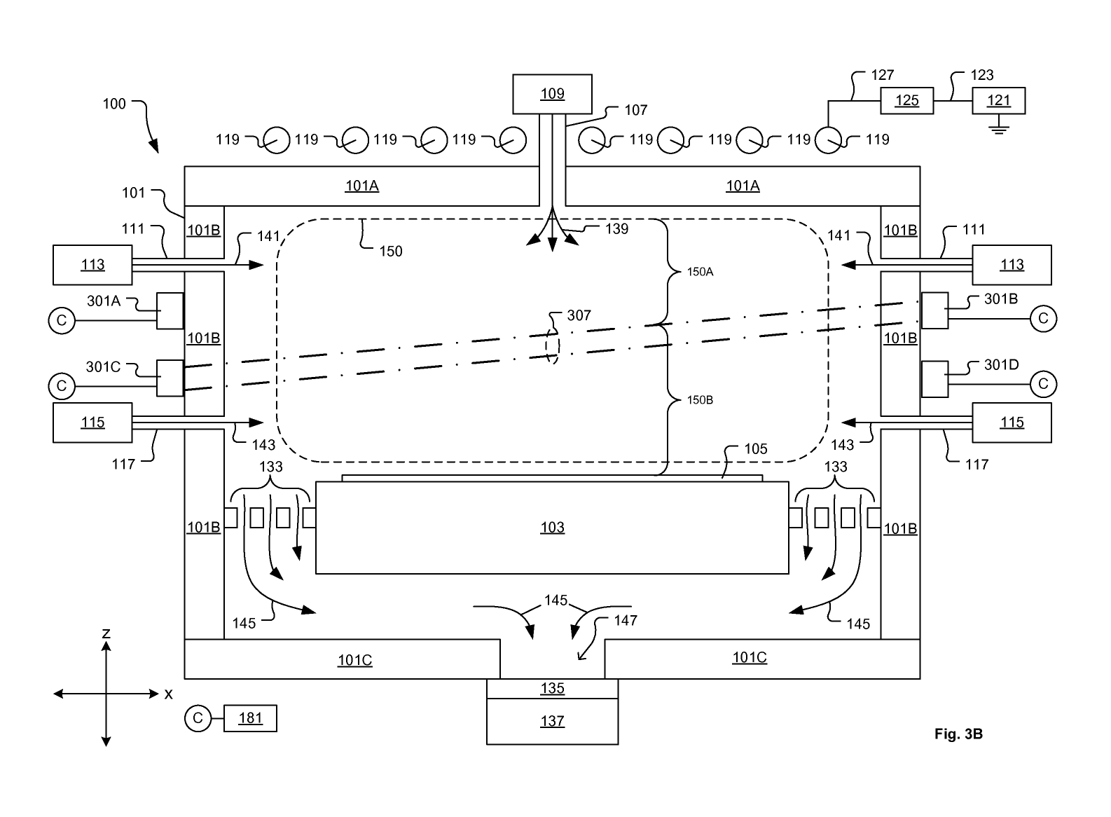

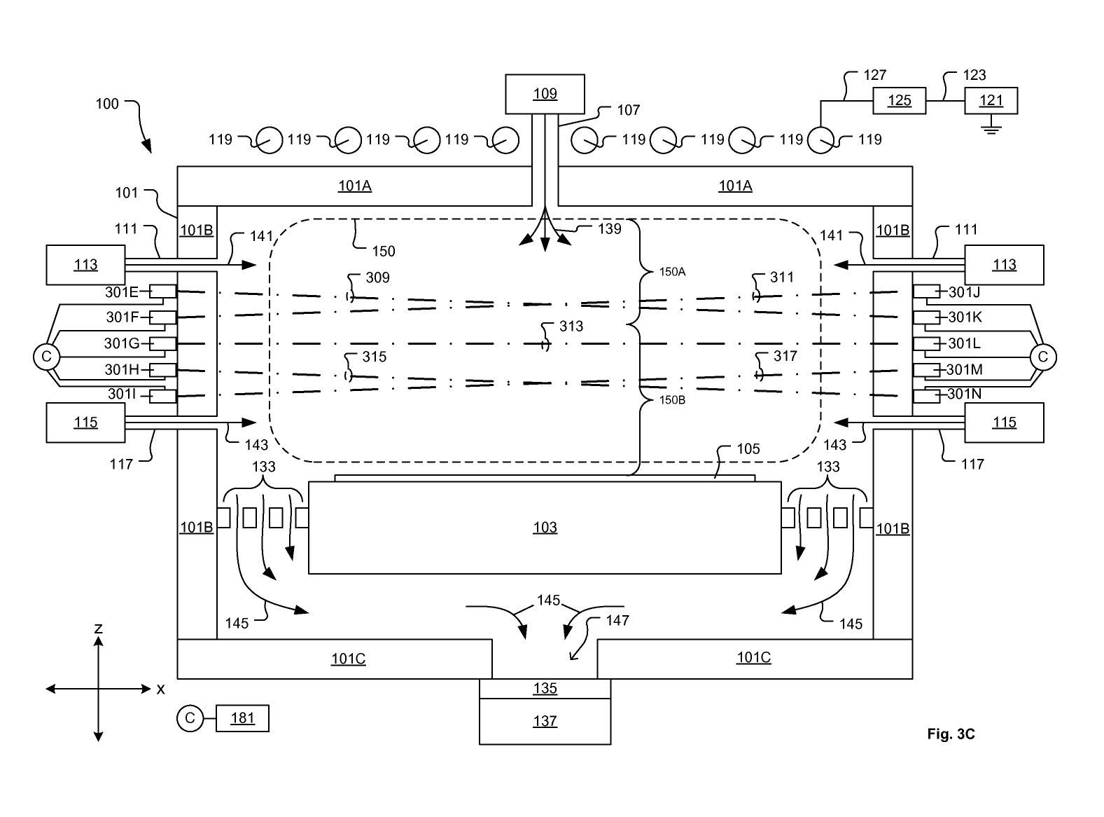

Also, in some embodiments, multiple vertically separated series of magnets can be used. For example, FIG. 3A shows the system 100 of FIG. 1A, with two vertically separated series of magnets, in accordance with some embodiments of the present invention. A first series of magnets includes magnets 301A and 301B, and a second series of magnets includes magnets 301C and 301D. Each series of magnets is disposed within a common horizontal plane (x-y plane) relative to the processing volume 150, so as to reside within a common annular band around the processing volume 150. Each magnet within the different vertically separated series of magnets can be either a permanent magnet or an electromagnet independently controllable by the magnetic field control system 181. In the embodiments where each magnet within the different vertically separated series of magnets is an electromagnet, the different magnets can be operated in a synchronous manner to generate a magnetic field within the processing volume 150 that has a prescribed three-dimensional shape. For example, in FIG. 3A, the first series of magnets that include magnets 301A and 301B are operated to generate a substantially horizontal magnetic field across the processing volume 150, as indicated by the horizontal lines 303 extending between the magnets 301A and 301B. And, the second series of magnets that include magnets 301C and 301D are operated to generate a substantially horizontal magnetic field across the processing volume 150, as indicated by the horizontal lines 305 extending between the magnets 301C and 301D.

In some embodiments that implement multiple vertically separated series of magnets, such as described with regard to FIG. 3A, a vertical separation distance (as measured in the z-axis direction) between vertically adjacent series of magnets is within a range extending from about 1 inch to about 2 inches. However, in other embodiments, the vertical separation distance (as measured in the z-axis direction) between vertically adjacent series of magnets can be as low as zero. Also, in various embodiments, essentially any number of vertically separated series of magnets can be utilized commensurate with geometric limitations imposed by surrounding structures of the system 100 and consideration of the vertical height of the processing volume 150.

FIG. 3B shows the system 100 of FIG. 3A, with the vertically separated series of magnets operated to generate a tilted magnetic field across the processing volume 150, in accordance with some embodiments of the present invention. Specifically, in the embodiments of FIG. 3B, the magnet 301C in the second series of magnets is operated in conjunction with the magnet 301B in the first series of magnets to generate the tilted magnetic field as indicated by angled lines 307 extending between the magnets 301C and 301B.

FIG. 3C shows the system 100 of FIG. 1A, with five vertically separated series of magnets, in accordance with some embodiments of the present invention. A first series of magnets includes magnets 301E and 301J. A second series of magnets includes magnets 301F and 301K. A third series of magnets includes magnets 301G and 301L. A fourth series of magnets includes magnets 301H and 301M. And, a fifth series of magnets includes magnets 301I and 301N. Each series of magnets is disposed within a respective common horizontal plane (x-y plane) relative to the processing volume 150, so as to reside within a respective common annular band around the processing volume 150. Each magnet within the different vertically separated series of magnets can be either a permanent magnet or an electromagnet independently controllable by the magnetic field control system 181.

In the embodiments where each magnet within the different vertically separated series of magnets is an electromagnet, the different magnets can be operated in a synchronous manner to generate a magnetic field within the processing volume 150 that has a prescribed three-dimensional shape. For example, in FIG. 3C, the first and second series of magnets are operated to generate crossing magnetic fields through the processing volume 150 that includes a first tilted magnetic field as indicated by angled line 309 extending between the magnets 301E and 301K, and a second tilted magnetic field as indicated by angled line 311 extending between the magnets 301F and 301J. Also, the third series of magnets are operated to generate a substantially horizontal magnetic field across the processing volume 150, as indicated by the horizontal line 313 extending between the magnets 301G and 301L. Also, the fourth and fifth series of magnets are operated to generate crossing magnetic fields through the processing volume 150 that includes a third tilted magnetic field as indicated by angled line 315 extending between the magnets 301H and 301N, and a fourth tilted magnetic field as indicated by angled line 317 extending between the magnets 301I and 301M.

The system 100 incorporating the series of magnets 151A-151P for magnetic confinement of charged constituents of the plasma can be particularly useful in mixed mode pulsing operations in which different processing steps are performed in a prescribed sequence, and possibly repetitive manner, to obtain a desired result on the substrate 105. For example, in some embodiments, mixed mode pulsing can be used to implement a systematic method for separating etching process steps in order to gain more control over etching process operations, such as by separating the processing steps of 1) etching, 2) sidewall protection/passivation through deposition, and 3) breakthrough of oxide on the horizontal surface of the substrate. The separate processing steps can be repeated in a systematic manner to achieve a desired etch profile on the substrate. With the system 100 incorporating the series of magnets 151A-151P, it is now possible to implement mixed mode processing recipes in which the substrate is exposed to a soft plasma (UV light and radicals) in some process steps, or to primarily UV light driven reactions in some process steps, or to primarily radical-driven reactions in some process steps, or to full plasma processing (ions, electrons, radicals, UV light) in some processing steps.

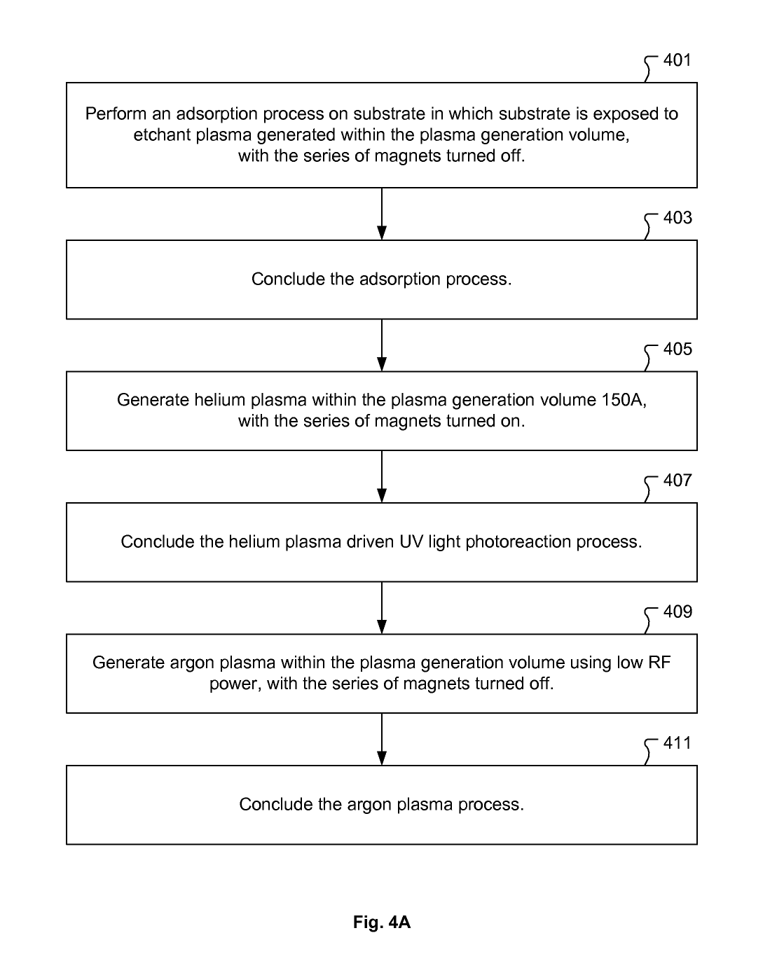

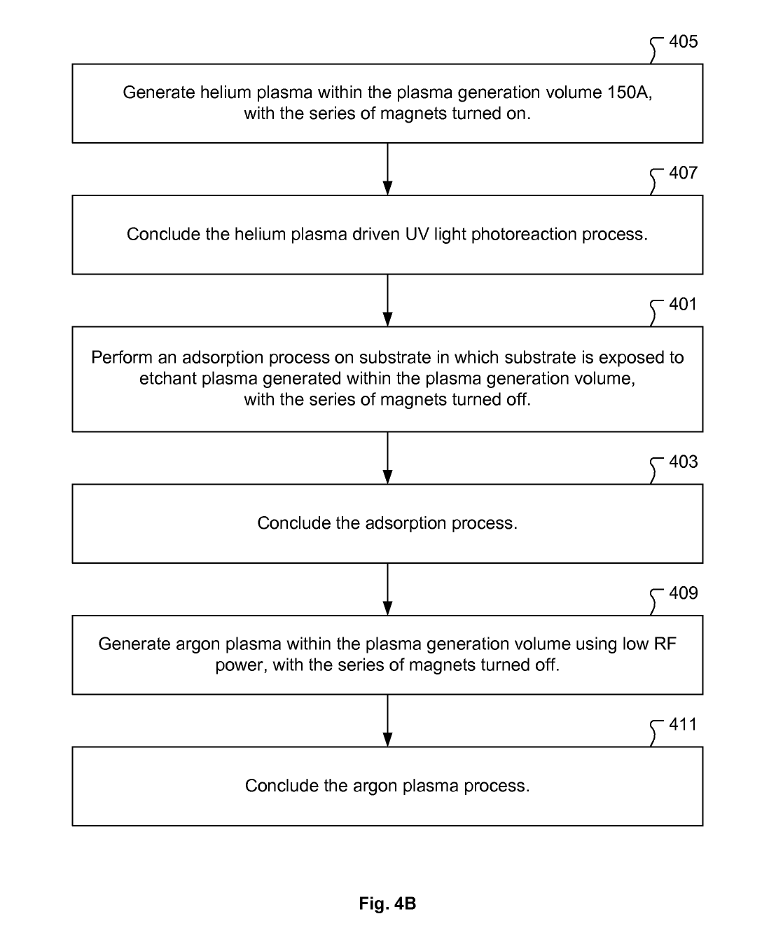

FIG. 4A shows a flowchart of a method for semiconductor device fabrication using the system 100 of FIG. 1A, in accordance with some embodiments of the present invention. The method includes an operation 401 for performing an adsorption process in which a substrate is exposed to etchant plasma generated within the plasma generation volume 150A, with the series of magnets 151A-151P turned off. In some embodiments, a Cl₂ process gas is used to generate the etchant plasma for operation 401. In some embodiments, the etchant plasma for operation 401 is generated with a low RF power in order to keep the plasma potential low. In operation 401, the substrate is not RF biased in order to avoid ion bombardment from the etchant plasma. In an operation 403, the adsorption process using the etchant plasma is concluded.

In an operation 405, a helium plasma is generated within the plasma generation volume 150A, with the series of magnets 151A-151P turned on. In operation 405, the ions and electrons of the helium plasma will be trapped in the plasma generation volume 150A by the magnetic fields generated by the series of magnets 151A-151P. Therefore, in operation 405, the substrate is exposed to high energy UV light emanating from the helium plasma and is not exposed to ions or electrons. The high energy UV light from the helium plasma will initiate photoreactions on the substrate surface. In an operation 407, the helium plasma driven UV light photoreaction process is concluded.

The method also includes an operation 409 in which an argon plasma is generated within the plasma generation volume 150A using a low RF power, with the series of magnets 151A-151P turned off. Because argon plasma does not generate much UV light, particularly when generated with a low RF power, the operation 409 provides for activation of the substrate surface by argon ions with minimum UV light exposure of the substrate. In an operation 411, the argon plasma process is concluded. FIG. 4B shows a flowchart of an alternate embodiment of the method of FIG. 4A, in which the operation 405 for UV light photoreaction processing using the helium plasma is performed before the adsorption process of operation 401, instead of after the adsorption process of operation 401, in accordance with some embodiments of the present invention.

It should be appreciated that the series of magnets 151A-151P can be configured and operated in many different ways to generate magnetic fields across the processing volume 150 having essentially any shape and strength as required to confine charged constituents of the plasma to the plasma generation volume 150A overlying the substrate 105, and in a temporally controlled manner, so as to control exposure of the substrate 105 (and even a particular portion thereof) to specifically selected constituents of the plasma (ions/electrons, radicals, UV light) at a given time. Therefore, use of the series of magnets 151A-151P to generate magnetic fields across the processing volume 150 provides for implementation of UV light specific plasma processing operations for semiconductor device fabrication that would not be possible otherwise.

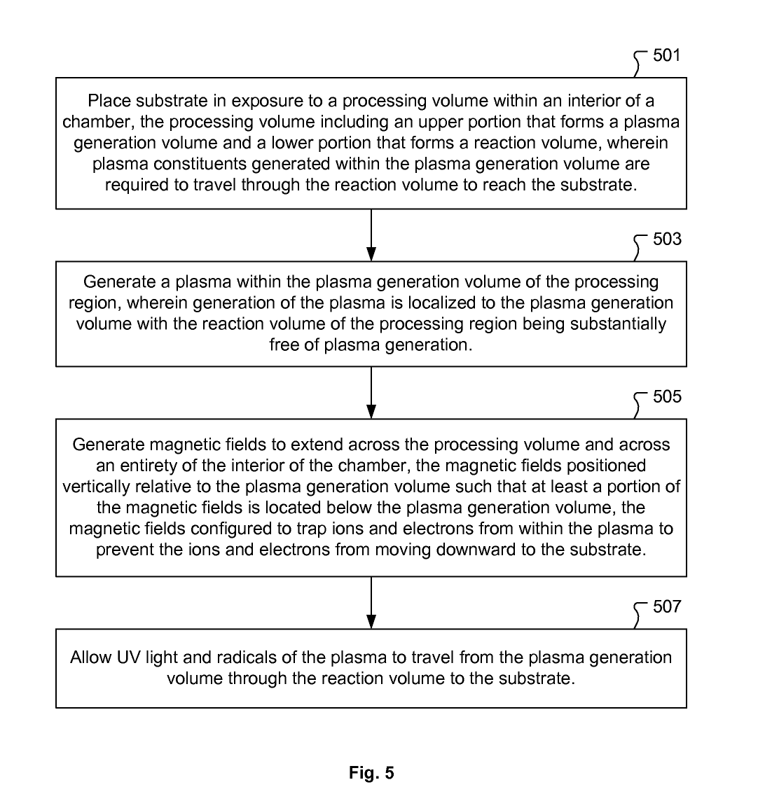

FIG. 5 shows a method for plasma processing of a substrate, in accordance with some embodiments of the present invention. The method includes an operation 501 in which a substrate is placed in exposure to a processing volume within an interior of a chamber. The processing volume includes an upper portion that forms a plasma generation volume and a lower portion that forms a reaction volume. Plasma constituents generated within the plasma generation volume are required to travel through the reaction volume to reach the substrate. The method also includes an operation 503 for generating a plasma within the plasma generation volume of the processing region. Generation of the plasma is localized to the plasma generation volume, with the reaction volume of the processing region being substantially free of plasma generation. In some embodiments, the plasma is a helium plasma generated to produce high energy UV light.

The method also includes an operation 505 for generating magnetic fields to extend across the processing volume. The magnetic fields are positioned vertically relative to the plasma generation volume such that at least a portion of the magnetic fields is located below the plasma generation volume and above the substrate. The magnetic fields are configured to trap ions and electrons from within the plasma to prevent the ions and electrons from moving downward to the substrate. In some embodiments, the magnetic fields are generated from multiple radial positions distributed in a substantially uniform manner around a radial periphery of the processing volume. In some embodiments, the magnetic fields are generated at a single vertical position around the radial periphery of the processing volume. In some embodiments, the magnetic fields are generated at multiple vertical positions around the radial periphery of the processing volume. The method also includes an operation 507 for allowing UV light and radicals of the plasma to travel from the plasma generation volume through the reaction volume to the substrate. Additionally, in some embodiments, the method can include an operation for flowing a lower region gas into the reaction volume at a vertical location between the magnetic fields and the substrate, and an operation for allowing the UV light to dissociate the lower region gas in exposure to the substrate.

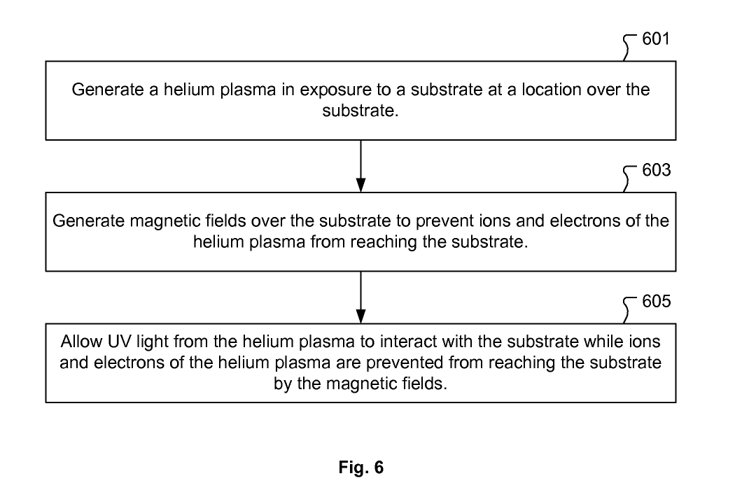

FIG. 6 shows a method for plasma processing of a substrate, in accordance with some embodiments of the present invention. The method includes an operation 601 for generating a helium plasma in exposure to a substrate at a location over the substrate. The method also includes an operation 603 for generating magnetic fields over the substrate to prevent ions and electrons of the helium plasma from reaching the substrate. The method also includes an operation 605 for allowing UV light from the helium plasma to interact with the substrate while ions and electrons of the helium plasma are prevented from reaching the substrate by the magnetic fields.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the described embodiments.

What is claimed is:

1. A system for plasma processing, comprising:
a chamber having an exterior structure including one or more side walls, a bottom structure, and a top dielectric window;
a substrate support structure disposed within an interior of the chamber, the substrate support structure having a top surface configured to support a substrate, a processing volume formed within the interior of the chamber between the top surface of the substrate support and the top dielectric window, an upper portion of the processing volume being a plasma generation volume, a lower portion of the processing volume being a reaction volume;
a coil antennae disposed above the dielectric window;
a radiofrequency (RF) power source connected to supply RF power to the coil antennae;
a process gas input positioned above the substrate processing volume;
a process gas supply plumbed to supply process gas to the process gas input and into the plasma generation volume; and
a series of magnets disposed around a radial periphery of the chamber at a location below the top dielectric window, the series of magnets configured to generate magnetic fields that extend across the processing volume, the series of magnets positioned relative to the plasma generation volume such that at least a portion of the magnetic fields generated by the series of magnets is located below the plasma generation volume.

2. The system for plasma processing as recited in claim 1, wherein the series of magnets includes multiple magnets disposed in a substantially uniform manner around an outer radial periphery of the chamber.

3. The system for plasma processing as recited in claim 1, wherein the series of magnets is located within a common annular band around the processing volume.

4. The system for plasma processing as recited in claim 1, wherein each magnet within the series of magnets is an electromagnet.

5. The system for plasma processing as recited in claim 4, further comprising:
a magnetic field control system configured to control a magnetic field strength generated by each electromagnet within the series of magnets in an independent manner, such that any one electromagnet can be turned on or off at a given time, and such that the magnetic field strength generated by any one electromagnet can be separately controlled at a given time.

6. The system for plasma processing as recited in claim 1, wherein the series of magnets is positioned outside the one or more side walls of the chamber.

7. The system for plasma processing as recited in claim 1, wherein the series of magnets is positioned within the one or more side walls of the chamber.

8. The system for plasma processing as recited in claim 1, wherein the series of magnets is positioned within the interior of the chamber.

9. The system for plasma processing as recited in claim 1, wherein a portion of the one or more side walls of the chamber located between a given magnet within the series of magnets and the interior of the chamber is formed of a material that does not significantly attenuate the magnetic field generated by the given magnet.

10. The system for plasma processing as recited in claim 9, wherein the portion of the one or more side walls of the chamber is formed of either aluminum, ceramic, or quartz.

11. The system for plasma processing as recited in claim 1, wherein each magnet within the series of magnets is a permanent magnet.

12. The system for plasma processing as recited in claim 1, wherein the series of magnets disposed around the radial periphery of the chamber at the location below the top dielectric window is a first series of magnets, wherein the system further includes at least one additional series of magnets disposed around the radial periphery of the chamber at another location below the top dielectric window, wherein each of the at least one additional series of magnets is located within a respective common annular band around the processing volume.

13. The system for plasma processing as recited in claim 1, further comprising:
a lower region gas input positioned to supply a lower region gas to a location within the reaction volume below the series of magnets without the lower region gas flowing through the plasma generation volume.

14. A method for plasma processing of a substrate, comprising:
placing a substrate in exposure to a processing volume within an interior of a chamber, the processing volume including an upper portion that forms a plasma generation volume and a lower portion that forms a reaction volume, wherein plasma constituents generated within the plasma generation volume are required to travel through the reaction volume to reach the substrate;
generating a plasma within the plasma generation volume of the processing region, wherein generation of the plasma is localized to the plasma generation volume, with the reaction volume of the processing region being substantially free of plasma generation;
generating magnetic fields to extend across the processing volume, the magnetic fields positioned vertically relative to the plasma generation volume such that at least a portion of the magnetic fields is located below the plasma generation volume and above the substrate, the magnetic fields configured to trap ions and electrons from within the plasma to prevent the ions and electrons from moving downward to the substrate; and
allowing ultraviolet (UV) light and radicals of the plasma to travel from the plasma generation volume through the reaction volume to the substrate.

15. The method for plasma processing of the substrate as recited in claim 14, wherein the plasma is a helium plasma generated to produce high energy UV light.

16. The method for plasma processing of the substrate as recited in claim 14, wherein the magnetic fields are generated from multiple radial positions distributed in a substantially uniform manner around a radial periphery of the processing volume.

17. The method for plasma processing of the substrate as recited in claim 16, wherein the magnetic fields are generated at a single vertical position around the radial periphery of the processing volume.

18. The method for plasma processing of the substrate as recited in claim 16, wherein the magnetic fields are generated at multiple vertical positions around the radial periphery of the processing volume.

19. The method for plasma processing of the substrate as recited in claim 14, further comprising:
flowing a lower region gas into the reaction volume at a vertical location between the magnetic fields and the substrate; and
allowing the UV light to dissociate the lower region gas in exposure to the substrate.

20. A method for plasma processing of a substrate, comprising:
generating a helium plasma in exposure to a substrate at a location over the substrate;
generating magnetic fields over the substrate to prevent ions and electrons of the helium plasma from reaching the substrate; and
allowing ultraviolet (UV) light from the helium plasma to interact with the substrate while ions and electrons of the helium plasma are prevented from reaching the substrate by the magnetic fields.
